(19) United States
(12) Patent Application Publication
(10) Pub. No.: US 2024/0389417 A1
(43) Pub. Date: Nov. 21, 2024

(54) DISPLAY PANEL AND DISPLAY DEVICE

(71) Applicants: Chengdu BOE Optoelectronics Technology Co., Ltd., Sichuan (CN); BOE Technology Group Co., Ltd., Beijing (CN)

(72) Inventors: Binyan WANG, Beijing (CN); Cong LIU, Beijing (CN); Yudiao CHENG, Beijing (CN)

(21) Appl. No.: 18/258,333

(22) PCT Filed: Jun. 22, 2022
(86) PCT No.: PCT/CN2022/100394

§ 371 Date: Jun. 20, 2023

(51) Int. Cl. H10K 59/131; H10K 59/121; H10K 59/13

(52) U.S. Cl. CPC H10K 59/1315; H10K 59/1213; H10K 59/1216; H10K 59/13

(57) ABSTRACT

A display panel has a primary display area and a secondary display area adjacent to each other, and includes a plurality of light emitting devices, a plurality of pixel circuits, a plurality of first connection wires, a plurality of second connection wires and a plurality of compensation portions. The plurality of second connection wires are connected between another part of the light emitting devices and another part of the pixel circuits. A capacitance per unit area of the second connection wires is smaller than a capacitance per unit area of the first connection wires. The plurality of compensation portions are correspondingly connected with the plurality of second connection wires.

### CROSS REFERENCE

The present application is based upon International Application No. PCT/CN2022/100394, filed on Jun. 22, 2022, and the entire contents thereof are incorporated herein by reference.

### TECHNICAL FIELD

The present disclosure relates to the field of display technologies, and in particular, to a display panel and a display device.

### BACKGROUND

With the continuous improvement of consumers' sensory pursuit for display screens and the continuous advancement of display panel industry technologies, in order to achieve a high screen-to-body ratio and achieve the ultimate viewing experience, a part of a display panel is configured as a display area (secondary display area) with a relatively high light transmittance, and a camera is disposed on the back of the secondary display area.

It should be noted that the information disclosed in the Background section above is only for enhancing the understanding of the background of the present disclosure, and thus may include information that does not constitute prior art known to those of ordinary skill in the art.

### SUMMARY

An objective of the present disclosure is to provide a display panel and a display device.

According to an aspect of the present disclosure, there is provided a display panel with a primary display area and a secondary display area adjacent to each other, and the display panel includes:
a plurality of light emitting devices arranged in an array in the secondary display area, including a first light emitting device and a second light emitting device;
a plurality of pixel circuits arranged in an array in the primary display area, including a first pixel circuit and a second pixel circuit;
a plurality of first connection wires connected between the first light emitting device and the first pixel circuit;
a plurality of second connection wires connected between the second light emitting device and the second pixel circuit, wherein a capacitance per unit area of the second connection wires is smaller than a capacitance per unit area of the first connection wires; and
a plurality of compensation portions correspondingly connected to the plurality of the second connection wires.

In an example embodiment of the present disclosure, the first light emitting device and the second light emitting device are located in the same row and have the same color, and the first light emitting device is closer to the primary display area than the second light emitting device. The first pixel circuit is closer to the secondary area than the second pixel circuit. The second connection wire is disposed on a side of the first connection wire away from the pixel circuit. Capacitances of the plurality of first connection wires and capacitances of the plurality of second connection wires connected with a plurality of first light emitting devices and a plurality of second light emitting devices in the same row increases or decreases linearly and sequentially along a direction of the secondary display area pointing to the primary display area.

In an example embodiment of the present disclosure, the first light emitting device and the second light emitting device are red light emitting devices and/or blue light emitting devices.

In an example embodiment of the present disclosure, the display panel further includes:
a substrate;
a first conductive layer disposed on a side of the substrate;
a first insulation layer disposed on a side of the first conductive layer away from the substrate; and
a second conductive layer disposed on a side of the first insulation layer away from the substrate.

In an example embodiment of the present disclosure, the first conductive layer includes the first connection wire, the second conductive layer includes the second connection wire, and the compensation portion is disposed at the first conductive layer and/or the second conductive layer.

In an example embodiment of the present disclosure, the compensation portion includes one or both of a first compensation portion and a second compensation portion; and the first compensation portion is disposed on the first conductive layer, the second compensation portion is disposed on the second conductive layer.

In an example embodiment of the present disclosure, the second compensation portion is disposed in a patterned manner, and a partial edge of the second compensation portion is connected with the second connection wire.

In an example embodiment of the present disclosure, the display panel further includes:
a second insulation layer disposed on a side of the second conductive layer away from the substrate; and
a third conductive layer disposed on a side of the second insulation layer away from the substrate;
wherein the third conductive layer includes the second connection wire, the second conductive layer includes the first connection wire, and the compensation portion is disposed at the first conductive layer and/or the second conductive layer and/or the third conductive layer.

In an example embodiment of the present disclosure, the compensation portion includes at least one of a first compensation portion disposed at the first conductive layer, a second compensation portion disposed at the second conductive layer, or a third compensation portion disposed at the third conductive layer.

In an example embodiment of the present disclosure, the first compensation portion includes:
a first portion connected to the second connection wire, wherein an orthographic projection of the first portion on the substrate is not overlapped with an orthographic projection of the second connection wire on the substrate; and
a second portion connected to the first portion, wherein an orthographic projection of the second portion on the substrate is located within the orthographic projection of the second connection wire on the substrate.

In an example embodiment of the present disclosure, the second compensation portion includes:
a third portion connected to the second connection wire, wherein an orthographic projection of the third portion on the substrate is not overlapped with the orthographic projection of the second connection wire on the substrate; and
a fourth portion connected to the third portion, wherein an orthographic projection of the fourth portion on the substrate is located within the orthographic projection of the second connection wire on the substrate.

In an example embodiment of the present disclosure, the third compensation portion is disposed in a patterned manner, and a partial edge of the third compensation portion is connected with the second connection wire.

In an example embodiment of the present disclosure, the compensation portion is disposed at the primary display area.

In an example embodiment of the present disclosure, the primary display area includes:
a normal display area; and
a transition area disposed between the secondary display area and the normal display area, wherein the pixel circuit is disposed at the transition area, and the compensation portion is disposed at the transition area.

In an example embodiment of the present disclosure, a plurality of pixel circuits in the same row include:
a first set of pixel circuits disposed close to the secondary display area;
a second set of pixel circuits disposed on a side of the first set of pixel circuits away from the secondary display area; and
a third set of pixel circuits disposed on a side of the second set of pixel circuits away from the secondary display area;
wherein the first set of pixel circuits is connected with the light emitting device through the first conductive layer, the second set of pixel circuits is connected with the light emitting device through the second conductive layer, and the third set of pixel circuits is connected with the light emitting device through the third conductive layer.

In an example embodiment of the present disclosure, the display panel further includes:
a plurality of third connection wires disposed at the first conductive layer, wherein the plurality of third connection wires are correspondingly connected between the first set of pixel circuits and the plurality of light emitting devices, the plurality of first connection wires are correspondingly connected between the second set of pixel circuits and the plurality of light emitting devices, and the plurality of second connection wires are correspondingly connected between the third set of pixel circuits and the plurality of light emitting devices.

In an example embodiment of the present disclosure, the first compensation portion is spaced apart from the third connection wire, and is located on a side of the third connection wire away from the secondary display area; and the second compensation portion is spaced apart from the first connection wire, and is located on a side of the first connection wire away from the secondary display area.

In an example embodiment of the present disclosure, ends of a plurality of first compensation portions close to the secondary display area are aligned, and ends of a plurality of second compensation portions close to the secondary display area are aligned.

In an example embodiment of the present disclosure,
the first compensation portion includes:
a first compensation section connected to the second connection wire; and
a first dummy section, spaced apart from the first compensation section and located on a side of the first compensation section close to the secondary display area;
the second compensation portion includes:
a second compensation section connected to the second connection wire; and
a second dummy section, spaced apart from the second compensation section and located on a side of the second compensation section close to the secondary display area;
wherein areas of orthographic projections of a plurality of first compensation sections on the substrate are the same, and areas of orthographic projections of a plurality of second compensation sections on the substrate are the same; and wherein ends of a plurality of first dummy sections close to the secondary display area are aligned, and ends of a plurality of second dummy sections close to the secondary display area are aligned.

In an example embodiment of the present disclosure, the plurality of light emitting devices in the same row include:
a plurality of green light emitting devices sequentially and correspondingly connected to a plurality of pixel circuits in the same row close to the secondary display area; and
a plurality of red light emitting devices and a plurality of blue light emitting devices alternately and correspondingly connected to a plurality of pixel circuits in the same row away from the secondary display area.

In an example embodiment of the present disclosure, a pixel density of the transition area is equal to a pixel density of the secondary display area, and a pixel density of the normal display area is greater than the pixel density of the secondary display area.

In an example embodiment of the present disclosure, an area of an orthographic projection of a light emitting device in the secondary display area on the substrate is smaller than an area of an orthographic projection of a light emitting device in the transition area on the substrate.

In an example embodiment of the present disclosure, the display panel further includes:
a fourth connection wire connected between a light emitting device closest to the primary display area and a pixel circuit closest to the secondary area, wherein the fourth connection wire is disposed at a source-drain layer of the pixel circuit.

According to another aspect of the present disclosure, a display device includes:
the display panel described in any one of the above embodiments;
a photosensitive sensor disposed at a non-display side of the display panel, wherein an orthographic projection of the photosensitive sensor on a display side is at least partially overlapped with the secondary display area.

It should be noted that the above general description and the following detailed description are merely exemplary and explanatory and should not be construed as limiting of the disclosure.

### BRIEF DESCRIPTION OF THE DRAWINGS

The drawings here are incorporated into the specification and constitute a part of the specification, show embodiments in accordance with the present disclosure, and are used together with the specification to explain the principle of the present disclosure. Obviously, the drawings in the following description are only some embodiments of the present disclosure. For those of ordinary skill in the art, other drawings can be obtained based on these drawings without creative work.

FIG. 1 is a schematic structural diagram of an area division of a display panel.

FIG. 2 is a schematic structural diagram of an arrangement of sub-pixels, pixel circuits and light emitting devices in each area of a display panel.

FIG. 3 is a schematic structural diagram of a connecting relationship between half of a row of light emitting devices in a secondary area and a pixel circuit.

FIG. 4 is a schematic diagram of a capacitance graph of a plurality of connection wires connecting a plurality of light emitting devices with a plurality of pixel circuits in the same row.

FIG. 5 is a schematic diagram of a light emitting brightness graph of a plurality of light emitting devices connected with connection wires in FIG. 4.

FIG. 6 is a schematic structural diagram of a pixel circuit.

FIG. 7 is a schematic structural diagram of a first example embodiment of a display panel of the present disclosure cut along a first connection wire.

FIG. 8 is a schematic structural diagram of a first example embodiment of a display panel of the present disclosure cut along a second connection wire.

FIG. 9 is a schematic top view of a first example embodiment of a display panel of the present disclosure at a second connection wire.

FIG. 10 is a schematic structural diagram of a second example embodiment of a display panel of the present disclosure cut along a second connection wire.

FIG. 11 is a schematic top view of a second example embodiment of a display panel of the present disclosure at a second connection wire.

FIG. 12 is a schematic structural diagram of a relationship between a third connection wire or a first connection wire and a first compensation portion or a second compensation portion.

FIG. 13 is a schematic structural diagram of a third example embodiment of a display panel of the present disclosure.

FIG. 14 is a schematic structural diagram of a fourth example embodiment of a display panel of the present disclosure.

FIG. 15 is a schematic structural diagram of a fifth example embodiment of a display panel of the present disclosure.

### DESCRIPTION OF REFERENCE SIGNS

10. pixel circuit; 101. first set of pixel circuits; 102. second set of pixel circuits; 103. third set of pixel circuits; 1001. first pixel circuit; 1002. second pixel circuit;
11. substrate; 12. light shielding layer; 13. buffer layer; 14. active layer; 15. gate insulation layer; 16. gate; 17. interlayer dielectric layer; 181. source; 182. drain; 19. passivation layer;
20. light emitting device; 201. first light emitting device; 202. second light emitting device; 21. first electrode; 22. pixel definition layer; 23. light emitting layer set; 24. second electrode; 25. encapsulation layer set;
31. first connection wire; 32. second connection wire; 33. compensation portion; 331. first compensation portion; 3311. first portion; 3312. second portion; 3312a. first compensation section; 3312b. first dummy section 332, second compensation portion; 3321, third portion; 3322, fourth portion; 3322a, second compensation section; 3322b, second dummy section; 333, third compensation portion; 34, third connection wire;
41. first conductive layer; 42. first insulation layer; 43. second conductive layer; 44. second insulation layer; 45. third conductive layer; 46. third insulation layer;
5. fourth connection wire;
100. drive backplane; 200. light emitting substrate;
R, red light emitting device; G, green light emitting device; B, blue light emitting device;
AA1, primary display area; AA11, transition area; AA12, normal display area; AA2, secondary display area; PX, sub-pixel;
X, first direction; Y, second direction.

### DETAILED DESCRIPTION

Example embodiments will now be described more fully with reference to the accompanying drawings. However, the example embodiments can be implemented in a variety of forms and should not be construed as being limited to the embodiments set forth herein; rather, these embodiments are provided so that the present disclosure will be more full and complete so as to convey the idea of the example embodiments to those skilled in this art. The same reference numerals in the drawings denote the same or similar structures, and the detailed description thereof will be omitted. In addition, the drawings are merely schematic representations of the present disclosure and are not necessarily drawn to scale.

Although the relative terms such as “above” and “below” are used in the specification to describe the relative relationship of one component to another component shown, these terms are only for convenience in this specification, for example, according to an exemplary direction shown in the drawings. It will be understood that if the device shown is flipped upside down, the component described as “above” will become a component “below” another component. When a structure is “on” another structure, it may mean that a structure is integrally formed on another structure, or that a structure is “directly” disposed on another structure, or that a structure is “indirectly” disposed on another structure through other structures.

The terms “one”, “a”, “the”, “said”, and “at least one” are used to indicate that there are one or more elements/components or the like; the terms “include” and “have” are used to indicate an open meaning of including and means that there may be additional elements/components/etc. in addition to the listed elements/components/etc.; the terms “first”, “second” and “third” etc. are used only as markers, and do not limit the number of objects.

In the present disclosure, it should be noted that the term “connected” is to be understood broadly, unless otherwise explicitly defined. For example, “connected” may be fixedly connected, or detachably connected, or integrally connected. Furthermore, they may be connected directly or indirectly via an intermediate medium. “And/or” is only used to describe an association relationship of associated objects, and it means that there can be three relationships. For example, “A and/or B” can represent the following three cases: only A; both A and B; only B. In addition, the character “/” throughout the text generally means that the objects associated thereby have an “or” relationship.

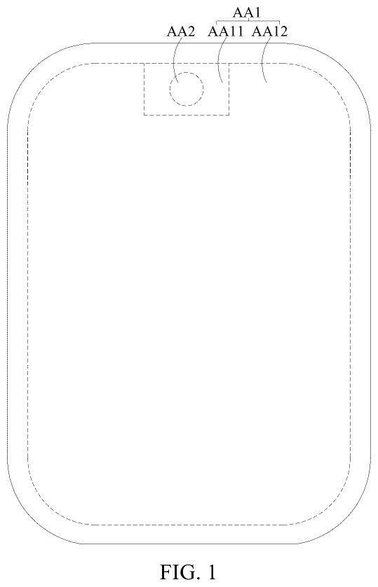

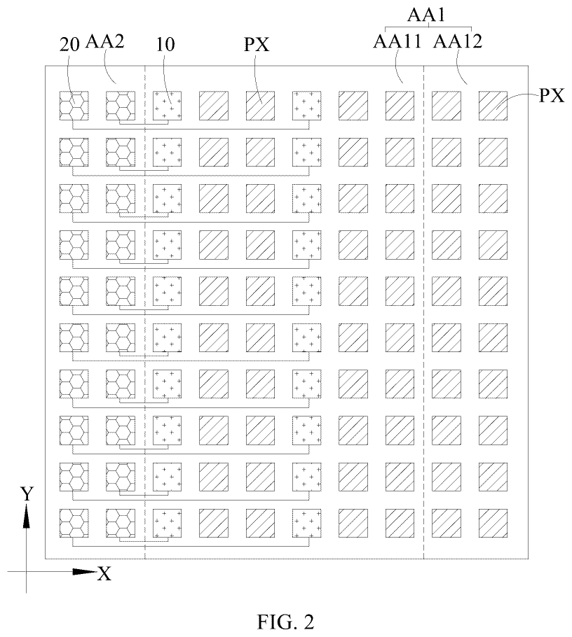

The inventors found that a main reason for the uneven brightness of light emitting devices 20 in a secondary area AA2 is that, referring to FIG. 1 and FIG. 2, in order to increase the light transmittance of the secondary area AA2, the secondary area AA2 is provided with the light emitting devices 20 only without a pixel circuit 10; a primary display area AA1 is provided with the pixel circuit 10 and a sub-pixel PX capable of normal display; the light emitting devices 20 in the secondary display area AA2 needs to be connected to the pixel circuit 10 in the primary display area AA1 through connection wires, and the light emission and light intensity of the light emitting devices 20 are driven through the pixel circuit 10.

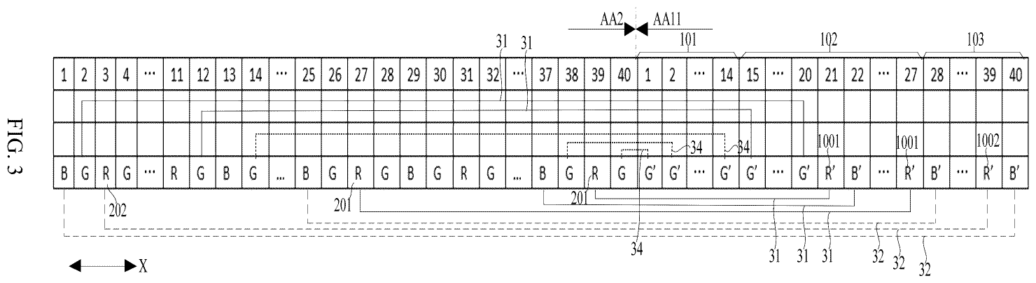

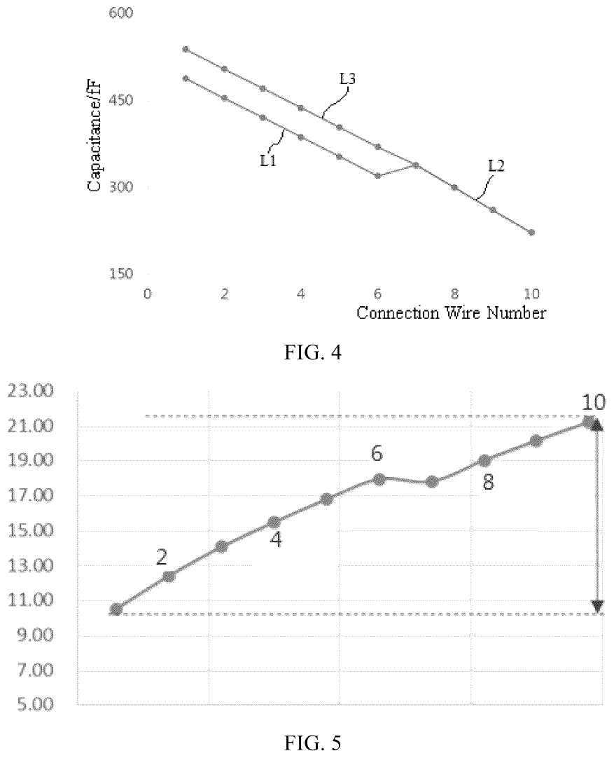

However, due to the limited space between two adjacent rows of light emitting devices 20, the connection wires need to be disposed on different conductive layers. The conductive layer closer to the pixel circuit 10 can form a capacitor with the conductor layer in the pixel circuit 10, and as a result, a capacitance per unit area of a conductive layer close to the pixel circuit 10 is greater than a capacitance per unit area of a conductive layer far away from the pixel circuit 10. Therefore, a capacitance difference between connection wires connected to the light emitting devices 20 in the same row is relatively large, failing to form a linear relationship. Referring to FIG. 4, for example, L2 represents capacitances of connection wires disposed on a conductive layer close to the pixel circuit 10, and the capacitances of these connection wires are relatively large; L1 represents capacitances of connection wires disposed on a conductive layer away from the pixel circuit 10, and the capacitances of these connection wires are relatively small. In particular, when two adjacent connection wires are located in different conductive layers, capacitances of the two adjacent connection wires will change abruptly, resulting in a difference in the brightness of the light emitting devices 20 in the same row. Referring to FIG. 5, an ordinate in FIG. 5 represents the brightness, and a number at each point represents a light-emitting device correspondingly connected with the connection wire in FIG. 4, and the maximum brightness difference is about 11.69.

An example embodiment of the present disclosure provides a display panel. As shown in FIGS. 1 to 13, the display panel has a primary display area AA1 and a secondary display area AA2 adjacent to each other, and the display panel may include a plurality of light emitting devices 20, a plurality of pixel circuits 10, a plurality of first connection wires 31, a plurality of second connection wires 32 and a plurality of compensation portions 33. The plurality of pixel circuits 10 are arranged in an array in the primary display area AA1, and include a first pixel circuit 1001 and a second pixel circuit 1002. The plurality of first connection wires 31 are connected between the first light emitting device 201 and the first pixel circuit 1001, and the plurality of second connection wires 32 are connected between the second light emitting device 202 and the second pixel circuit 1002. A capacitance per unit area of the second connection wires 32 is smaller than a capacitance per unit area of the first connection wires 31. The plurality of compensation portions 33 are correspondingly connected with the plurality of second connection wires 32.

In the display panel of the present disclosure, the capacitance per unit area of the second connection wires 32 is smaller than the capacitance per unit area of the first connection wires 31, and the plurality of compensation portions 33 are connected to the plurality of second connection wires 32 in a one-to-one correspondence. The capacitance of the second connection wire 32 is compensated by the compensation portion 33 to increase the capacitance of the second connection wire 32 and reduce the difference between the capacitance of the second connection wire 32 and the capacitance of the first connection wire 31, thereby reducing the brightness difference of the light emitting device 20.

The display panel can be an Organic Electroluminescence Display (OLED) display panel, a Quantum Dot Light Emitting Diode (QLED) display panel, and the like. The display panel has a light emitting side and a non-light emitting side disposed opposite to each other, and the light emitting side can display a picture, a side that displays the picture is a display side. The OLED display panel has the characteristics of self-illumination, high brightness, wide viewing angle, fast response time, and R, G, and B full-color components capable of being manufactured, so it is regarded as a star product of the next-generation display.

The OLED is taken as an example for description below.

In the example embodiment, as shown in FIG. 1, the display panel can be divided into the secondary display area AA2 and the primary display area AA1, and the primary display area AA1 can include a transition area AA11 and a normal display area AA12. The transition area AA11 surrounds the primary display area AA1, and the normal display area AA12 surrounds the transition area AA11.

The display panel is suitable for a display panel in which a camera is installed under a screen. The secondary display area AA2 is correspondingly installed with a camera component, and the normal display area AA12 is used for displaying a picture. The transition area AA11 and the secondary display area AA2 also need to display the picture, however, the secondary display area AA2 also needs to enable the light to be transmitted to the camera on the non-display side, and the camera can utilize the light transmitted to the non-display side to operate. In order to avoid a pixel element (such as a thin film transistor, the light emitting device 20, etc.) in the secondary display area AA2 blocking the camera, only the transparent light emitting device 20 is disposed in the secondary display area AA2 without disposing the pixel circuit 10. It should be understood that the light emitting device 20 in the secondary display area AA2 in the following description refers to the transparent light emitting device 20.

Moreover, in order to increase the light transmittance of the secondary display area AA2, an area of an orthographic projection of the light emitting device 20 in the secondary display area AA2 on the substrate 11 can be configured to be smaller than an area of an orthographic projection of a light emitting device 20 in the transition area AA11 on the substrate 11. For example, the area of the orthographic projection of the light emitting device 20 in the secondary display area AA2 on the substrate 11 may be one third to two thirds of the area of the orthographic projection of the light emitting device 20 in the transition area AA11 on the substrate 11, and specifically may be one-half.

However, the light emitting device 20 disposed in the secondary area AA2 needs to be driven by the pixel circuit 10 to emit light. Accordingly, the plurality of pixel circuits 10 are disposed in the transition area AA11, and the pixel circuits 10 in the transition area AA11 are connected with the light emitting devices 20 in the secondary area AA2 through connection wires.

Referring to FIG. 2, one small box in the figure represents one pixel area, and the display panel includes a plurality of pixel areas arranged in an array. Pixel areas of the normal display area AA12, pixel areas of the transition area AA11 and pixel areas of the secondary display area AA2 have the consistent arrangement.

A plurality of sub-pixels PX capable of normal display are arranged in an array in the normal display area AA12, and one pixel area is provided with one sub-pixel PX. A plurality of sub-pixels PX capable of normal display and a plurality of pixel circuits 10 are arranged in an array in the transition area AA11, and one pixel area is provided with one sub-pixel PX or one pixel circuit 10. Two sub-pixels PX and one pixel circuit 10 can be disposed as a group, and the pixel circuit 10 is disposed between two sub-pixels PX. A plurality of light emitting devices 20 are arranged in an array in the secondary display area AA2, and one pixel area is provided with one light emitting device 20. The sub-pixel PX includes the pixel circuit 10 and the light emitting device 20.

It should be noted that a first direction X is taken as a row, and a second direction Y is taken as a column. The pixel circuit 10 in the transition area AA11 is connected with the light emitting device 20 of the same row in the secondary area AA2, so as to avoid more intersections being generated by the connection wires between the pixel circuit 10 and the light emitting device 20 to affect the layout of the connection wires. The more the intersections, the easier the signal interference is generated.

Since the transition area AA11 is provided with the plurality of pixel circuits 10, a pixel density of the transition area AA11 is lower than a pixel density of the normal display area AA12, and the pixel density of the transition area AA11 can be the same as that of the secondary display area AA2. Note that, it is also possible that the pixel density of the transition area AA11 is greater than the pixel density of the secondary display area AA2.

It should be noted that not only the camera can be installed in the secondary display area AA2, but other light-sensitive sensors such as an infrared sensing device and a fingerprint sensor can also be installed.

The pixel circuit 10 includes at least a switching transistor and a driving transistor, and may further include structures such as a threshold compensation transistor and a storage capacitor. Referring to FIG. 6, an example pixel circuit 10 is presented. The pixel circuit 10 may specifically include a storage capacitor C1, a first transistor T1, a second transistor T2, a third transistor T3, a fourth transistor T4, a fifth transistor T5, a sixth transistor T6 and a seventh transistor T7.

A first terminal of the first transistor T1 is connected with a data line DATA, a second terminal of the first transistor T1 is connected with a N1 node, and a control terminal of the first transistor T1 is connected with a scan line Gate. A first terminal of the second transistor T2 is connected with the N1 node, a second terminal of the second transistor T2 is connected with a N3 node, and a control terminal of the second transistor T2 is connected with a N2 node. A first terminal of the third transistor T3 is connected with the N3 node, a second terminal of the third transistor T3 is connected with the N2 node, and a control terminal of the third transistor T3 is connected with the scan line Gate. A first terminal of the fourth transistor T4 is connected with the N2 node, a second terminal of the fourth transistor T4 is connected with an initialization voltage line Vint1, and a control terminal of the fourth transistor T4 is connected with a first reset line Reset1. A first terminal of the fifth transistor T5 is connected with a power line VDD, a second terminal of the fifth transistor T5 is connected with the N1 node, and a control terminal of the fifth transistor T5 is connected with a control signal line EM. A first terminal of the sixth transistor T6 is connected with the N3 node, a second terminal of the sixth transistor T6 is connected with a N4 node, and a control terminal of the sixth transistor T6 is connected with the control signal line EM. A first terminal of the seventh transistor T7 is connected with an initialization voltage line Vint2, a second terminal of the seventh transistor T7 is connected with the N4 node, and a control terminal of the seventh transistor T7 is connected with a second reset line Reset2. A first electrode of the storage capacitor C1 is connected with the power line VDD, and a second electrode of the storage capacitor C1 is connected with the N2 node. A first electrode 21 of the light emitting device 20 is connected with the N4 node, and a second electrode 24 of the light emitting device 20 is connected with a second power line VSS.

The used transistors mentioned above can be thin film transistors or field effect transistors or the same devices with other characteristics. Since the source 181 and the drain 182 of the used transistor are symmetrical, the source 181 and the drain 182 have no difference. In an embodiment of the present disclosure, in order to distinguish, the source 181 of the transistor is called the first terminal, the drain 182 of the transistor is called the second terminal, and the gate 16 of the transistor is called the control terminal. In addition, depending on the characteristics of the transistor, the transistor can be classified into a N-type transistor and a P-type transistor. When the P-type transistor is used, the first terminal is the source 181 of the P-type transistor, the second terminal is the drain 182 of the P-type transistor, and when a low level is input to the gate 16, the source 181 and the drain 182 are turned on. When the N-type transistor is used, the first terminal is the source 181 of the N-type transistor, the second terminal is the drain 182 of the N-type transistor, and when a high level is input to the gate 16, the source 181 and the drain 182 are turned on. The above-mentioned transistors in the pixel circuit 10 being the N-type transistors is taken as an example for description. It is conceivable that an implementation in which the P-type transistors are used can be easily thought of by those skilled in the art without creative efforts, so it is also within the protection scope of the embodiments of the present disclosure.

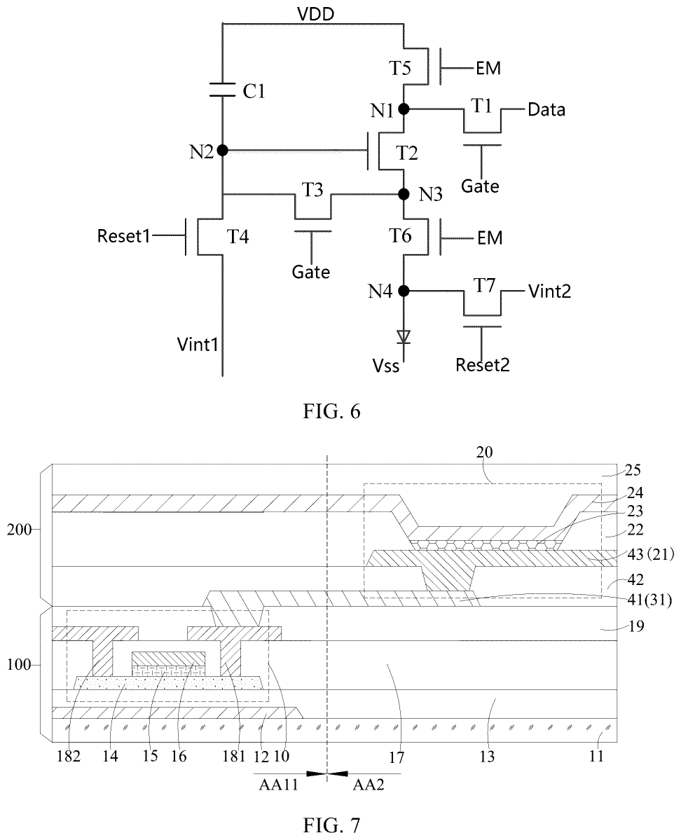

Referring to FIGS. 7-11, only one thin film transistor is shown in the figure, and the pixel circuit 10 will be described in detail below by taking one thin film transistor as an example. The display panel may include a driving backplane 100 and a light emitting substrate 200, the driving backplane 100 may include a plurality of pixel circuits 10 arranged in an array, the light emitting substrate 200 may include a plurality of light emitting devices 20 arranged in an array, and the pixel circuit 10 may drive the light emitting device 20 to emit light.

Specifically, the driving backplane 100 may include a substrate 11, and a material of the substrate 11 may include an inorganic material, for example, the inorganic material may be glass, quartz, or metal. The material of the substrate 11 may also include an organic material, for example, the organic material may be a resin material such as polyimide, polycarbonate, polyacrylate, polyetherimide, polyethersulfone, polyethylene terephthalate, and polyethylene naphthalate. The substrate 11 may be formed of a plurality of material layers, for example, the substrate 11 may include a plurality of base layers, and a material of the base layer may be any one of the above-mentioned materials. Note that, the substrate 11 can also be disposed as a single layer, which can be any one of the above materials.

A side of the substrate 11 can further be provided with a light shielding layer 12, and the light injected into an active layer 14 from the substrate 11 will generate photocarriers in the active layer 14, thereby greatly affecting the characteristics of the thin film transistor, and ultimately affecting the display quality of a display device. The light incident from the substrate 11 can be blocked by the light shielding layer 12, so as to avoid affecting the characteristics of the thin film transistor and the display quality of the display device.

A buffer layer 13 can also be formed on a side of the light shielding layer 12 away from the substrate 11. The buffer layer 13 plays the role of blocking water vapor and impurity ions in the substrate 11 (especially the organic material), and plays the role of adding hydrogen ions to the subsequently formed active layer 14. A material of the buffer layer 13 is an insulation material, which can insulate and isolate the light shielding layer 12 from the active layer 14.

A side of the buffer layer 13 away from the substrate 11 is provided with the active layer 14, and the active layer 14 may include a channel portion and conductor portions disposed at both ends of the channel portion. A side of the active layer 14 away from the substrate 11 is provided with a gate insulation layer 15, a side of the gate insulation layer 15 is provided with the gate 16, a side of the gate 16 is provided with an interlayer dielectric layer 17, and the interlayer dielectric layer 17 is provided with a first via hole in communication with the conductor portion. A side of the interlayer dielectric layer 17 away from the substrate 11 is provided with the source 181 and the drain 182, and the source 181 and the drain 182 are respectively connected to the two conductor portions through two corresponding first via holes. A side of the source 181 and the drain 182 away from the substrate 11 is provided with a passivation layer 19, and the passivation layer 19 is provided with a second via hole connected to the source 181. The active layer 14, the gate 16, the source 181 and the drain 182 form the thin film transistor.

It should be noted that the thin film transistor described in this specification is a top-gate thin film transistor. In other example embodiments of the present disclosure, the thin film transistor may also be a bottom-gate or dual-gate thin film transistor, and a specific structure thereof will not be described here. repeat. Furthermore, in a case where thin film transistors with opposite polarities are used or a direction of current changes during the circuit operation, functions of the “source 181” and the “drain 182” may be interchanged. Therefore, in this specification, the “source 181” and the “drain 182” can be interchanged with each other.

Since the pixel circuit 10 is not disposed in the secondary display area AA2, the driving backplane 100 may include the substrate 11, the buffer layer 13, the gate insulation layer 15, the interlayer dielectric layer 17, the passivation layer 19 and so on stacked in sequence in the secondary display area AA2. Structures of the driving backplane 100 in the normal display area AA12 and in the transition area AA11 may be the same.

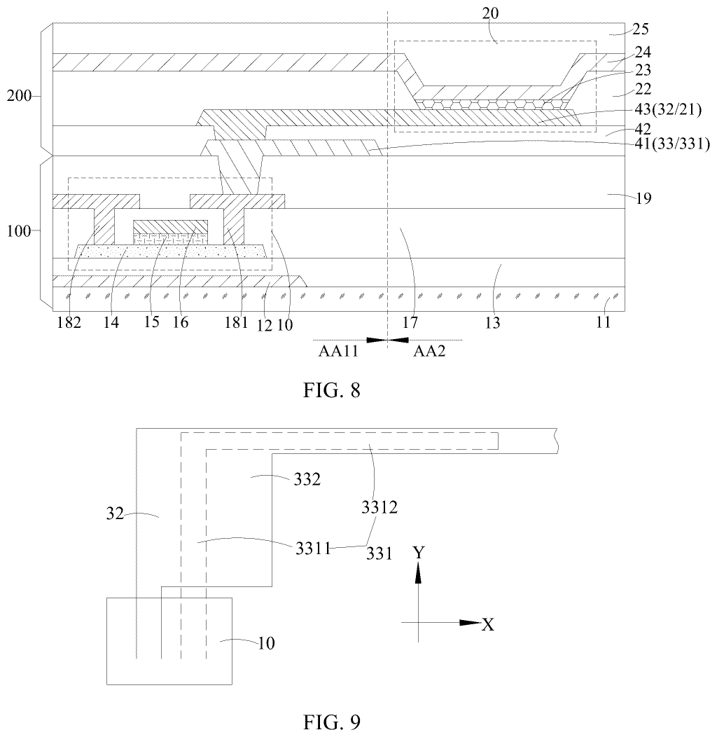

With continued reference to FIGS. 7 and 8, a side of the passivation layer 19 away from the substrate 11 is provided with a first conductive layer 41, a side of the first conductive layer 41 away from the substrate 11 is provided with a first insulation layer 42, and a side of the first insulation layer 42 away from the substrate 11 is provided with a second conductive layer 43.

In a case where the secondary display area AA2 has a small area and is provided with fewer light emitting devices 20, only the first conductive layer 41 and the second conductive layer 43 may be disposed. Reference to FIG. 7, the first conductive layer 41 may include a first connection wire 31, and the first connection wire 31 may extend from the transition area AA11 to the secondary display area AA2. Specifically, an end of the first connection wire 31 is connected to the source 181 through the second via hole disposed on the passivation layer 19, and the other end of the first connection wire 31 is connected to the first electrode 21 of the light emitting device 20.

The first conductive layer 41 may be a transparent conductive layer, that is, a material of the first conductive layer 41 may be Indium Tin Oxide (ITO), Indium Zinc Oxide (IZO) and the like.

In some other example embodiments of the present disclosure, most of the first connection wire 31 may be disposed in the secondary display area AA2, and only a small part of the first connection wire 31 extends to the transition area AA11. The source 181 of the thin film transistor in the transition area AA11 extends to a side of the secondary display area AA2 to form a first supplementary connection wire, and the first supplementary connection wire extends to an edge of the transition area AA11, and then the first connection wire 31 is connected to the first supplementary connection wire through the second via hole disposed on the passivation layer 19. In this way, a part of the connection wire connecting the light emitting device 20 and the thin film transistor located in the secondary display area AA2 (the first connection wire 31) is s made of the transparent conductive material, while a part of the connection wire located in the transition area AA11 (the first supplementary connection wire) is made of the metal material, which can reduce the resistance of the connection wire and improve the display brightness.

Referring to FIG. 8, the second conductive layer 43 may include a second connection wire 32 which may extend from the transition area AA11 to the secondary display area AA2. Specifically, an end of the second connection wire 32 is connected to the source 181 through the second via hole disposed on the passivation layer 19 and a third via hole disposed on the first insulation layer 42, and the other end of the second connection wire 32 is connected to the first electrode 21 of the light emitting device 20.

The second conductive layer 43 may be a transparent conductive layer, that is, a material of the second conductive layer 43 may be Indium Tin Oxide (ITO), Indium Zinc Oxide (IZO) and the like.

In a case where a source-drain layer is disposed in one layer, due to the limited space between two adjacent rows of light emitting devices 20, it is impossible to accommodate all the connection wires in one layer. The above-mentioned source-drain layer has been provided with the first supplementary connection wire, and thus, the second connection wire 32 can extend from the transition area AA11 to the secondary area AA2 to connect the pixel circuit 10 and the light emitting device 20.

In some other example embodiments of the present disclosure, in a case where the source-drain layer is disposed in two layers, that is, the above-mentioned source-drain layer is a first source-drain layer, and the side of the passivation layer 19 away from the substrate 11 is also provided with a second source-drain layer. The second source-drain layer may include a connection electrode and a second supplementary connection wire, and the connection electrode is connected with the second supplementary connection wire. The connection electrode is connected to the source 181 through the second via hold disposed on the passivation layer 19, and the second supplementary connection wire extends to the edge of the transition area AA11. A side of the second source-drain layer away from the substrate 11 is provided with the insulation layer, and a side of the insulation layer away from the substrate 11 is provided with the first conductive layer 41, the first insulation layer 42 and second conductive layer mentioned above in sequence.

Most of the second connection wire 32 may be disposed in the secondary display area AA2, and only a small part of the second connection wire 32 extends to the transition area AA11. The second connection wire 32 is connected to the second supplementary connection wire through a fourth via hole disposed on the insulation layer. In this way, a part of the connection wire connecting the light emitting device 20 and the thin film transistor located in the secondary display area AA2 (the second connection wire 32) is made of the transparent conductive material, while a part of the connection wire located in the transition area AA11 (the second supplementary connection wire) is made of the metal material, which can reduce the resistance of the connection wire and improve the display brightness.

In addition, since the first connection wire 31 is closer to the conductive layer of the pixel circuit 10 than the second connection wire 32, the first connection wire 31 forms a capacitor with the conductor layer in the pixel circuit 10, so that the capacitance per unit area of the first connection wire 31 is larger than the capacitance per unit area of the second connection wire 32. As a result, a capacitance difference between the first connection wire 31 and the second connection wire 32 connecting the same row of light emitting devices 20 is relatively large, failing to form a linear result, and even if the algorithm compensation is subsequently performed, the brightness difference still occurs.

Referring to FIG. 9, a second compensation portion 332 may be disposed on the second conductive layer 43, and the second compensation portion 332 is disposed in a patterned manner. The second compensation portion 332 may be disposed in the transition area AA11. Since the second connection wire 32 is led out from the pixel circuit 10 and bent into a gap between two adjacent rows of pixel circuits 10 and extends along the gap, the second compensation portion 332 is configured in a rectangular structure, so that two side edges of the second compensation portion 332 are connected with the second connection wire 32, that is, an end of the second connection wire 32 close to the pixel circuit 10 is patterned. The capacitance of the second connection wire 32 can be increased by the second compensation portion 332, so that a difference between the capacitance of the second connection wire 32 and the capacitance of the first connection wire 31 is reduced, thereby reducing the brightness difference of the light emitting device 20. Note that, the second compensation portion 332 can also be disposed as various polygons or patterns with arc-shaped sides.

Referring to FIG. 3, a first light emitting device 201, a second light emitting device 202, a first pixel circuit 1001 and a second pixel circuit 1002 are marked by taking a red light emitting device as an example. A plurality of first connection wires 31 are connected between a plurality of first light emitting devices 201 and a plurality of first pixel circuits 1001 arranged in the first direction X in a one-to-one correspondence, and a plurality of second connection wires 32 are connected between a plurality of second light emitting devices 202 and a plurality of second pixel circuits 1002 arranged in the first direction X in a one-to-one correspondence. The plurality of first light emitting devices 201 and the plurality of second light emitting devices 202 are located in the same row and have the same color, and the first light emitting device 201 is closer to the primary display area AA1 than the second light emitting device 202, and the first pixel circuit 1001 is closer to the secondary display area AA2 than the second pixel circuit 1002. The first direction X is a direction from the secondary display area AA2 to the primary display area AA1, and it should be noted that a direction from the primary display area AA1 to the secondary display area AA2 is also the first direction X. Specifically, the first direction X is taken as a row, or the first direction X is a row direction.

Along a direction from the secondary area AA2 to the primary display area AA1, capacitances of the plurality of first connection wires 31 and the plurality of second connection wires 32 connecting the plurality of first light emitting devices 201 and the plurality of second light emitting devices 202 in the same row increases or decreases linearly and sequentially.

Specifically, with reference to FIG. 4, L3 in the figure is a graph formed by the compensated capacitance of the plurality of second connection wires 32, and L3 and L2 in the figure substantively form a straight line. Compensating the capacitance of the second connection wire 32 through the compensation portion 33 needs to meet requirements that: along a direction from the secondary area AA2 to the primary display area AA1, capacitances of the plurality of first connection wires 31 and the plurality of second connection wires 32 connecting the plurality of first light emitting devices 201 and the plurality of second light emitting devices 202 in the same row increases or decreases linearly and sequentially, and the capacitance difference between two adjacent first connection wires 31 is substantially the same, the capacitance difference between two adjacent second connection wires 32 is substantially the same, and the capacitance difference between the adjacent first connection wire 31 and second connection wire 32 is substantially the same.

Reference is made to a capacitance comparison table before and after compensation for a second connection wire 32 connected with a red light emitting device R shown in Table 1.

TABLE 1

| | | before | after |
|---|---|---|---|
| | | compensation | compensation |
| | number | (capacitance/fF) | (capacitance/fF) |
| a second connection | 3 | 488.36 | 538.67 |
| wire 32 connected with | 7 | 454.81 | 505.12 |
| a red light emitting | 11 | 421.25 | 471.56 |
| device R | 15 | 387.52 | 437.83 |
| | 19 | 353.96 | 404.28 |
| | 23 | 320.40 | 370.71 |
| a first connection wire | 27 | 339.43 | 339.43 |
| 31 connected with a red | 31 | 300.33 | 300.33 |
| light emitting device R | 35 | 261.55 | 261.55 |
| (without the capacitance | 39 | 222.77 | 222.77 |
| compensation) | | | |

Therefore, magnitudes of areas of second compensation portions 332 connected with respective second connection wires 32 can be configured according to the above requirements.

In addition, referring to FIGS. 8 and 9, a first compensation portion 331 may also be disposed on the first conductive layer 41, and the first compensation portion 331 may include a first portion 3311 and a second portion 3312, and the second portion 3312 is connected with the first portion 3311. The first portion 3311 extends along the second direction Y, the second portion 3312 extends along the first direction X, and a connection between the second portion 3312 and the first portion 3311 forms a corner.

The first portion 3311 is connected with the second connection wire 32. Specifically, the first portion 3311 can be connected to the source 181 through a fifth via hole on the passivation layer 19, thereby connecting the second connection wire 32 with the first portion 3311 through the source 181. The first portion 3311 and the second connection wire 32 are connected to the source 181 through different via holes, therefore, an orthographic projection of the first portion 3311 on the substrate 11 is not overlapped with an orthographic projection of the second connection wire 32 on the substrate 11. Note that, in some other example embodiments of the present disclosure, the first portion 3311 may be connected to the source 181 first, and the second connection wire 32 is then connected to the first portion 3311. In this case, the orthographic projection of the first portion 3311 on the substrate 11 may be overlapped with the orthographic projection of the second connection wire 32 on the substrate 11.

A plurality of second connection wires 32 between two adjacent rows of pixel circuits 10 need to be compensated, and since a length of the second portion 3312 in the first direction X is shorter than a length of the second connection wires 32 in the first direction X, an orthographic projection of the second portion 3312 on the substrate 11 is located within the orthographic projection of the second connection wire 32 on the substrate 11, that is, the second portion 3312 is overlapped with the second connection wire 32, which is convenient for accommodating a plurality of first compensation portions 331; and it is convenient for calculation during design. In addition, a capacitor can also be formed between the first compensation portion 331 and the second connection wire 32, which further increases the capacitance of the second connection wire 32.

It should be noted that the first compensation portion 331 and the second compensation portion 332 may be disposed at the same time, or only the first compensation portion 331 may be disposed, or only the second compensation portion 332 may be disposed.

In some example embodiments of the present disclosure, a fourth compensation portion may also be disposed on the first conductive layer 41, and the fourth compensation portion may be disposed in a patterned manner. The fourth compensation portion may be disposed in the transition area AA11. Since the first compensation portion 331 is led out from the pixel circuit 10 and bent into the gap between two adjacent rows of pixel circuits 10, and extends along the gap, the fourth compensation portion is configured as a rectangular structure, so that two side edges of the fourth compensation portion are connected with the first compensation portion 331, that is, an end of the first compensation portion 331 close to the pixel circuit 10 is patterned. The capacitance of the second connection wire 32 can be increased by the fourth compensation portion 33, so that a difference between the capacitance of the second connection wire 32 and the capacitance of the first connection wire 31 is reduced, thereby reducing the brightness difference of the light emitting device 20.

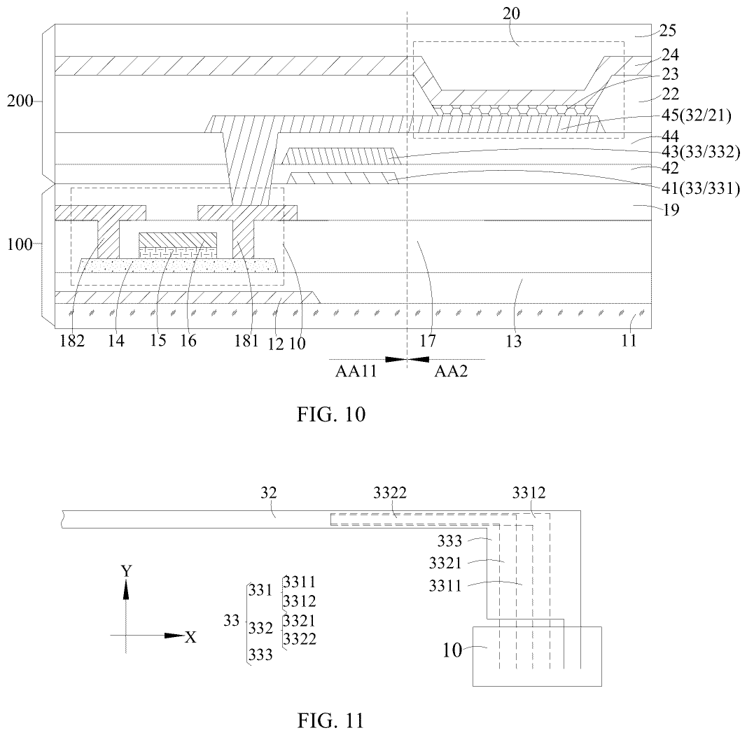

Referring to FIG. 10, the display panel may further include a second insulation layer 44 and a third conductive layer 45. Specifically, the second insulation layer 44 is disposed on a side of the second conductive layer 43 away from the substrate 11, and the third conductive layer 45 is disposed on a side of the second insulation layer 44 away from the substrate 11. The third conductive layer 45 may include the second connection wire 32, the second conductive layer 43 may include the first connection wire 31, and the compensation portion 33 is disposed on the first conductive layer 41 and/or the second conductive layer 43 and/or the third conductive layer 45.

The third conductive layer 45 may be a transparent conductive layer, that is, a material of the third conductive layer 45 may be Indium Tin Oxide (ITO), Indium Zinc Oxide (IZO) and the like.

Specifically, in a case where the secondary display area AA2 has a relatively large area and is provided with more light emitting devices 20, the first conductive layer 41, the second conductive layer 43 and the third conductive layer 45 can be disposed. The connection wires connecting the pixel circuits 10 and the light emitting devices 20 can be disposed on the first conductive layer 41, the second conductive layer 43 and the third conductive layer 45, so that in a case where two adjacent rows of light emitting devices 20 have the same gap, more connection wires are accommodated to meet the purpose of the secondary display area AA2 having a relatively large area and being provided with more light emitting devices 20.

Since the first conductive layer 41 is closer to the conductive layer of the pixel circuit 10 than the second conductive layer 43, the first conductive layer 41 forms a capacitor with the conductor layer in the pixel circuit 10, so that the capacitance per unit area of the first conductive layer 41 is relatively large. The second conductive layer 43 can form the capacitors with both the first conductive layer 41 and the third conductive layer 45, so that the capacitance per unit area of the second conductive layer 43 is also relatively large. However, the third conductive layer 45 can only form the capacitor with the second conductive layer 43, so that the capacitance per unit area of the third conductive layer 45 is smaller than the capacitances per unit area of the first conductive layer 41 and the second conductive layer 43.

Therefore, when the second connection wires 32 connecting the light emitting devices 20 in the same row are disposed on the third conductive layer 45, and the first connection wires 31 connecting the light emitting devices 20 in the same row are disposed on the second conductive layer 43, the capacitance per unit area of the first connection wires 31 is larger than the capacitance per unit area of the second connection wire 32. As a result, a capacitance difference between the first connection wire 31 and the second connection wire 32 connecting the same row of light emitting devices 20 is relatively large, failing to form a linear result, and even if the algorithm compensation is subsequently performed, the brightness difference still occurs.

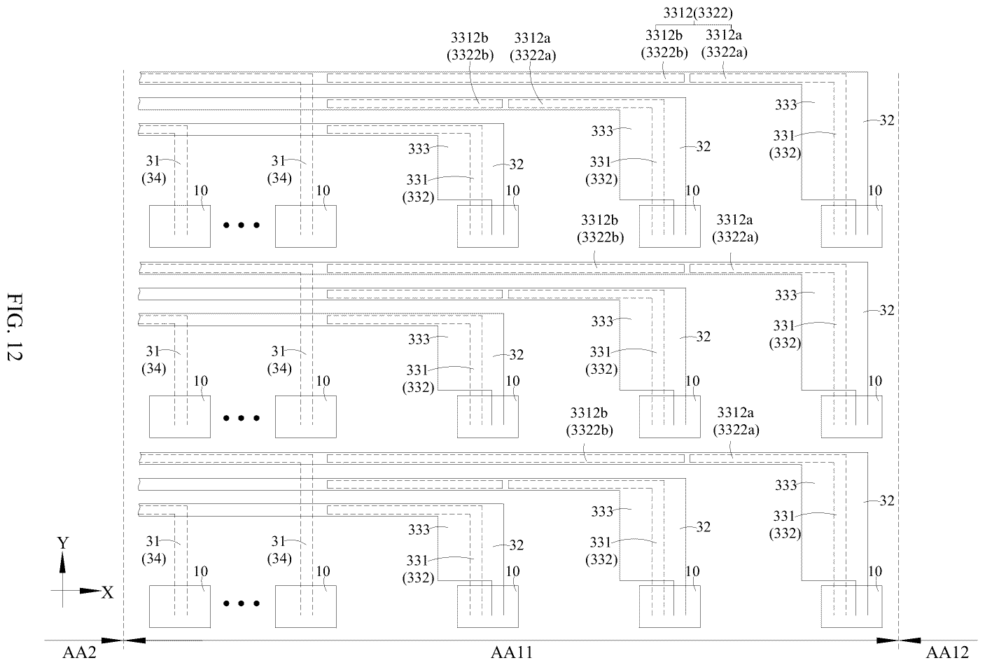

In some example embodiments of the present disclosure, referring to FIGS. 10 and 11, in order to distinguish the second connection wire 32, the second portion 3312 and the fourth portion 3322 in FIG. 11, their widths are drawn differently, and their widths in actual products can be configured as required. A first compensation portion 331 may be disposed on the first conductive layer 41, and the first compensation portion 331 may include a first portion 3311 and a second portion 3312, and the second portion 3312 is connected with the first portion 3311. The first portion 3311 extends along the second direction Y, the second portion 3312 extends along the first direction X, and a connection between the second portion 3312 and the first portion 3311 forms a corner.

The first portion 3311 is connected with the second connection wire 32. Specifically, the first portion 3311 can be connected to the source 181 through a fifth via hole on the passivation layer 19, thereby connecting the second connection wire 32 with the first portion 3311 through the source 181. The first portion 3311 and the second connection wire 32 are connected to the source 181 through different via holes, therefore, an orthographic projection of the first portion 3311 on the substrate 11 is not overlapped with an orthographic projection of the second connection wire 32 on the substrate 11. Note that, in some other example embodiments of the present disclosure, the first portion 3311 may be connected to the source 181 first, and the second connection wire 32 is then connected to the first portion 3311. In this case, the orthographic projection of the first portion 3311 on the substrate 11 may be overlapped with the orthographic projection of the second connection wire 32 on the substrate 11.

A plurality of second connection wires 32 between two adjacent rows of pixel circuits 10 need to be compensated, and since a length of the second portion 3312 in the first direction X is shorter than a length of the second connection wires 32 in the first direction X, an orthographic projection of the second portion 3312 on the substrate 11 is located within the orthographic projection of the second connection wire 32 on the substrate 11, that is, the second portion 3312 is overlapped with the second connection wire 32, which is convenient for accommodating a plurality of first compensation portions 331; and it is convenient for calculation during design. In addition, a capacitor can also be formed between the first compensation portion 331 and the second connection wire 32, which further increases the capacitance of the second connection wire 32.

In some example embodiments of the present disclosure, with continued reference to FIGS. 10 and 11, a second compensation portion 332 may be disposed at the second conductive layer 43, and the second compensation portion 332 may include a third portion 3321 and a fourth portion 3322, the fourth portion 3322 is connected with the third portion 3321. The third portion 3321 extends along the second direction Y, the fourth portion 3322 extends along the first direction X, and a connection between the fourth portion 3322 and the third portion 3321 forms a corner.

The third portion 3321 is connected with the second connection wire 32. Specifically, the third portion 3321 can be connected to the source 181 through the via hole on the passivation layer 19 and the first insulation layer 42, thereby connecting the second connection wire 32 with the third portion 3321 through the source 181. Since third portion 3321 and the second connection wire 32 are connected to the source 181 through different via holes, an orthographic projection of the third portion 3321 on the substrate 11 is not overlapped with an orthographic projection of the second connection wire 32 on the substrate 11. Note that, in some other example embodiments of the present disclosure, the third portion 3321 may be connected to the source 181 first, and the second connection wire 32 is then connected to the third portion 3321. In this case, the orthographic projection of the third portion 3321 on the substrate 11 may be overlapped with the orthographic projection of the second connection wire 32 on the substrate 11.

A plurality of second connection wires 32 between two adjacent rows of pixel circuits 10 need to be compensated, and since a length of the fourth portion 3322 in the first direction X is shorter than a length of the second connection wires 32 in the first direction X, an orthographic projection of the fourth portion 3322 on the substrate 11 is located within the orthographic projection of the second connection wire 32 on the substrate 11, that is, the fourth portion 3322 is overlapped with the second connection wire 32, which is convenient for accommodating a plurality of second compensation portions 332; and it is convenient for calculation during design. In addition, a capacitor can also be formed between the second compensation portion 332 and the second connection wire 32, which further increases the capacitance of the second connection wire 32.

In some example embodiments of the present disclosure, with continued reference to FIG. 11, a third compensation portion 333 may be disposed on the third conductive layer 45, and the third compensation portion 333 is disposed in a patterned manner. The third compensation portion 333 may be disposed in the transition area AA11. Since the second connection wire 32 is led out from the pixel circuit 10 and bent into a gap between two adjacent rows of pixel circuits 10 and extends along the gap, the third compensation portion 333 is configured in a rectangular structure, so that two side edges of the third compensation portion 333 are connected with the second connection wire 32, that is, an end of the second connection wire 32 close to the pixel circuit 10 is patterned. The capacitance of the second connection wire 32 can be increased by the third compensation portion 333, so that a difference between the capacitance of the second connection wire 32 and the capacitance of the first connection wire 31 is reduced, thereby reducing the brightness difference of the light emitting device 20. Note that, the third compensation portion 333 can also be disposed as various polygons or patterns with arc-shaped sides.

A plurality of first connection wires 31 and a plurality of second connection wires 32 are connected with a plurality of light emitting devices 20 arranged along the first direction X in a one-to-one correspondence. Serial numbers of the plurality of light emitting devices 20 are arranged along the first direction X, and serial numbers of the plurality of first connection wires 31 and the plurality of second connection wires 32 are the same as the serial numbers of the plurality of light emitting devices 20 with which the plurality of first connection wires 31 and the plurality of second connection wires 32 are connected. With reference to FIG. 4, L3 in the figure is a graph of the compensated capacitance of the plurality of second connection wires 32, and L3 and L2 in the figure substantively form a straight line. Compensating the capacitance of the second connection wire 32 through the compensation portion 33 needs to meet requirements that: the capacitances of the plurality of first connection wires 31 and the capacitances of the plurality of second connection wires 32 are linear according to the serial numbers, for example, the capacitances of the plurality of first connection wires 31 and the capacitances of the plurality of second connection wires 32 increase or decrease sequentially according to the serial numbers; and the capacitance difference between two adjacent first connection wires 31 is the same, the capacitance difference between two adjacent second connection wires 32 is the same, and the capacitance difference between the adjacent first connection wire 31 and second connection wire 32 is the same.

Therefore, magnitudes of areas of the third compensation portion 333, the first compensation portion 331 and the second compensation portion 332 connected with respective second connection wires 32 can be configured according to the above requirements.

It should be noted that the first compensation portion 331, the second compensation portion 332 and the third compensation portion 333 may be disposed at the same time. Only the first compensation portion 331 may be disposed, or only the second compensation portion 332 may be disposed, or only the third compensation portion 333 may be disposed. Two of the first compensation portion 331, the second compensation portion 332 and the third compensation portion 333 may also be disposed, which may be determined according to the capacitance that needs to be compensated actually.

In some example embodiments of the present disclosure, a fourth compensation portion may also be disposed on the first conductive layer 41, and the fourth compensation portion may be disposed in a patterned manner. The fourth compensation portion may be disposed in the transition area AA11. Since the first compensation portion 331 is led out from the pixel circuit 10 and bent into the gap between two adjacent rows of pixel circuits 10, and extends along the gap, the fourth compensation portion is configured as a rectangular structure, so that two side edges of the fourth compensation portion are connected with the first compensation portion 331, that is, an end of the first compensation portion 331 close to the pixel circuit 10 is patterned. The capacitance of the second connection wire 32 can be increased by the fourth compensation portion, so that a difference between the capacitance of the second connection wire 32 and the capacitance of the first connection wire 31 is reduced, thereby reducing the brightness difference of the light emitting device 20.

In addition, a fifth compensation portion may also be disposed on the second conductive layer 43, and the fifth compensation portion may be disposed in a patterned manner. The fifth compensation portion may be disposed in the transition area AA11. Since the first compensation portion 331 is led out from the pixel circuit 10 and bent into the gap between two adjacent rows of pixel circuits 10, and extends along the gap, the fifth compensation portion is configured as a rectangular structure, so that two side edges of the fifth compensation portion are connected with the first compensation portion 331, that is, an end of the first compensation portion 331 close to the pixel circuit 10 is patterned. The capacitance of the second connection wire 32 can be increased by the fifth compensation portion, so that a difference between the capacitance of the second connection wire 32 and the capacitance of the first connection wire 31 is reduced, thereby reducing the brightness difference of the light emitting device 20.

It should be noted that the fourth compensation portion and the fifth compensation portion can also be disposed as various polygons or patterns with arc-shaped sides.

Referring to FIG. 3, different line types are used in the figure to indicate that the connection wires are disposed on different conductive layers, and the figure shows a connecting relationship between half of a row of light emitting devices 20 in the secondary area AA2 and the pixel circuit 10. The reasons is that, the secondary display area AA2 is generally disposed symmetrically, and the transition area AA11 is also disposed symmetrically. The light emitting device 20 on the left half of the secondary display area AA2 is connected with the pixel circuit 10 on the corresponding side, and the light emitting device 20 on the right half of the secondary display area AA2 is connected with the pixel circuit 10 on the corresponding side. In the figure, a pixel circuit connected with a green light emitting device G is marked as G′, a pixel circuit connected with a red light emitting device R is marked as R′, and a pixel circuit connected with a blue light emitting device B is marked as B′.

In this example embodiment, a plurality of pixel circuits 10 in the same row may include a first set of pixel circuits 101, a second set of pixel circuits 102 and a third set of pixel circuits 103, and the first set of pixel circuits 101, the second set of pixel circuits 102 and the third set of pixel circuits 103 are disposed in sequence away from the secondary display area AA2. Specifically, the first set of pixel circuits 101 is disposed close to the secondary display area AA2, and there may be fourteen pixel circuits 10 in the first set of pixel circuits 101; the second set of pixel circuits 102 is disposed on a side of the first set of pixel circuits 101 away from the secondary display area AA2, and there may be thirteen pixel circuits 10 in the second set of pixel circuits 102; and the third set of pixel circuits 103 is disposed on a side of the second set of pixel circuits 102 away from the secondary display area AA2, and there may be thirteen pixel circuits 10 in the third set of pixel circuits 103. The number of pixel circuits 10 each included in the first set of pixel circuits 101, the second set of pixel circuits 102 and the third set of pixel circuits 103 can be configured as required.

The first set of pixel circuits 101 is connected with the light emitting device 20 through the first conductive layer 41, the second set of pixel circuits 102 is connected with the light emitting device 20 through the second conductive layer 43, and the third set of pixel circuits 103 is connected with the light emitting device 20 through the third conductive layer 45. Specifically, the first conductive layer 41 may include fourteen third connection wires 34, the fourteen third connection wires 34 are correspondingly connected between the fourteen pixel circuits 10 in the first set of pixel circuits 101 and fourteen light emitting devices 20, and the fourteen light emitting devices 20 may all be green light emitting devices G; the thirteen first connection wires 31 are correspondingly connected between the thirteen pixel circuits 10 in the second set of pixel circuits 102 and the thirteen light emitting devices 20, six of the thirteen light emitting devices 20 can be green light emitting devices G, three of them can be blue light emitting devices B, and four of them can be red light emitting devices R; a plurality of second connection wires 32 are correspondingly connected between the plurality of pixel circuits 10 in the third set of pixel circuits 103 and a plurality of light emitting devices 20, seven of the thirteen light emitting devices 20 may be blue light emitting devices B, and six of them may be red light emitting devices R.

In this way, as shown in FIG. 3 and FIG. 12, the third connection wire 34 only occupies a part of the transition area AA11 close to the secondary display area AA2, while a part of the transition area AA11 close to the normal display area AA12 is not occupied. Therefore, the part of the transition area AA11 close to the normal display area AA12 can be provided with the first compensation portion 331, and the first compensation portion 331 and the third connection wire 34 are spaced apart, the first compensation portion 331 is located on a side of the third connection wire 34 away from the secondary display area, and the third connection wire 34 and the first compensation portion 331 belong to the first conductive layer 41, so as to prevent the first compensation portion 331 from affecting the arrangement and electrical performance of the third connection wire 34. Moreover, ends of the plurality of first compensation portions 331 close to the secondary display area AA2 may be aligned. Specifically, the second portion 3312 of the first compensation portion 331 may include a first compensation section 3312a and a first dummy section 3312b. The first compensation section 3312a is connected with the second connection wire 32, that is, the first compensation section 3312a is connected with the first portion 3311, and is connected with the second connection wire 32 through the first portion 3311. The first dummy section 3312b is spaced apart from the first compensation section 3312a, and is located on a side of the first compensation section 3312a close to the secondary display area AA2. The first compensation section 3312a has the function of capacitance compensation for the second connection wire 32, and the first dummy section 3312b has no function of capacitance compensation for the second connection wire 32, and is only used for maintaining etch uniformity. Orthographic projections of the plurality of first compensation sections 3312a on the substrate 11 have the same area, that is, lengths of the plurality of first compensation sections 3312a in the first direction X are the same, and widths of the plurality of first compensation sections 3312a in the second direction Y are the same, so that capacitances compensated by the plurality of first compensation sections 3312a for the plurality of second connection wires 32 are the same.

It should be noted that the plurality of first compensation portions 331 can also be configured to the same length, so that capacitances compensated by the plurality of first compensation portions 331 for the corresponding plurality of second connection wires 32 are the same, and then ends of the plurality of first compensation portions 331 close to the secondary display area AA2 may not be aligned.

Similarly, referring to FIG. 3 and FIG. 12, the first connection wire 31 only occupies a part of the transition area AA11 close to the secondary display area AA2, while a part of the transition area AA11 close to the normal display area AA12 is not occupied. Therefore, the second compensation portion 332 can be disposed in the part of the transition area AA11 close to the normal display area AA12, and the second compensation portion 332 is spaced apart from the first connection wire 31. The second compensation portion 332 is located on a side of the first connection wire 31 away from the secondary display area, and the first connection wire 31 and the second compensation portion 332 belong to the second conductive layer 42, so as to prevent the second compensation portion 332 from affecting the arrangement and electrical performance of the first connection wire 31. Moreover, ends of the plurality of second compensation portions 332 close to the secondary display area AA2 may be aligned. Specifically, the fourth portion 3322 of the second compensation portion 332 may include a second compensation section 3322a and a second dummy section 3322b, the second compensation section 3322a is connected with the second connection wire 32, that is, the second compensation section 3322a is connected with the third portion 3321, and is connected with the second connection wire 32 through the third portion 3321. The second dummy section 3322b is spaced apart from the second compensation section 3322a, and is located on the side of the second compensation section 3322a close to the secondary display area. The second compensation section 3322a has the function of capacitance compensation for the second connection wire 32, and the second dummy section 3322b has no function of capacitance compensation for the second connection wire 32, and is only used for maintaining etch uniformity. Orthographic projections of the plurality of second compensation sections 3322a on the substrate 11 have the same area, that is, lengths of the plurality of second compensation sections 3322a in the first direction X are the same, and widths of the plurality of second compensation sections 3322a in the second direction Y are the same, so that the capacitances compensated by the plurality of second compensation sections 3322a for the plurality of second connection wires 32 are the same.

It should be noted that the plurality of second compensation portions 332 can also be configured to the same length, so that capacitances compensated by the plurality of second compensation portions 332 for the corresponding plurality of second connection wires 32 are the same, and then ends of the plurality of second compensation portions 332 close to the secondary display area AA2 may not be aligned.

It should be noted that, in other example embodiments of the present disclosure, the compensation portion 33 can be disposed in the secondary display area AA2. For example, the plurality of light emitting devices 20 in the same row of the secondary display area AA2 can be divided into a plurality of sets according to a distance from the transition area AA11, and each set of light emitting devices 20 is connected with the pixel circuit 10 in the transition area AA11 through the connection wires in one layer of conductive layer, so that the connection wire does not occupy the secondary display area AA2, and the compensation portion can be disposed on a part of the conductive layer where no connection wire is disposed. That is to say, a connecting manner of the light emitting device 20 in the secondary display area AA2 is the same as a connecting manner of the pixel circuit 10 in the transition area AA11.

Referring to FIG. 3, in this example embodiment, a plurality of light emitting devices 20 in the same row may include a plurality of green light emitting devices G, a plurality of red light emitting devices R, and a plurality of blue light emitting devices B, whose arrangement manner may be BGRG. The plurality of green light emitting devices G are sequentially and correspondingly connected with a plurality of pixel circuits 10 in the same row close to the secondary display area AA2; that is, the plurality of green light emitting devices G are sequentially and correspondingly connected with the plurality of pixel circuits 10 in the first set of pixel circuits 101 and the plurality of pixel circuits 10 in the second set of pixel circuits 102 close to the secondary display area AA2. The plurality of red light emitting devices R and the plurality of blue light emitting devices B are alternately and correspondingly connected with a plurality of pixel circuits 10 in the same row away from the secondary display area AA2, that is, the plurality of red light emitting devices R and the plurality of blue light emitting devices B are alternately and correspondingly connected with the plurality of pixel circuits 10 in the third set of pixel circuits 103 and the plurality of pixel circuits 10 in the second set of pixel circuits 102 away from the secondary display area AA2.

In this way, a length of the connection wire connecting the green light emitting device G and the pixel circuit 10 is shorter, which can be called a green-first connection manner. Since an inductive driving speed of a light emitting material of the green light emitting device G is relatively slow, if the green light emitting device G is driven simultaneously with the red light emitting device R and the blue light emitting device B, a light emitting speed of the green light emitting device G will lag behind light emitting speeds of the red light emitting device R and the blue light emitting device B, causing the overall display panel to present purple. A length of the connection wire connecting the green light emitting device G and the pixel circuit 10 is designed to be short, so that the green light emitting device G can be driven in advance, so that the green light emitting device G emits light almost simultaneously with the red light emitting device R and the blue light emitting device B, so that the display panel can display normally without presenting purple as a whole.

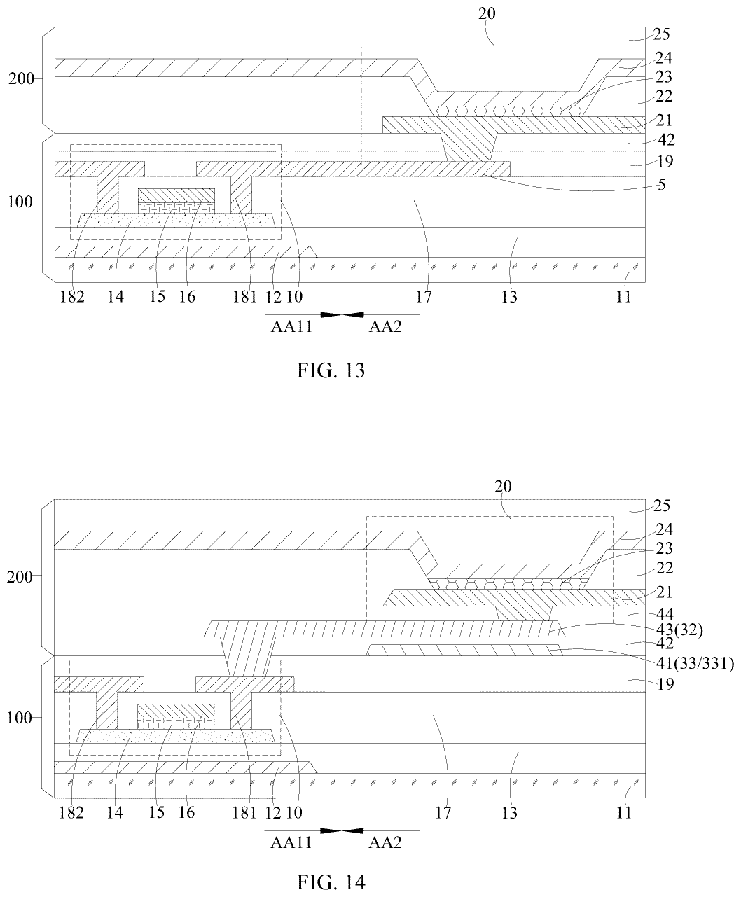

Referring to FIG. 13, the display panel may further include a fourth connection wire 5 connected between a light emitting device 20 closest to the primary display area AA1 and a pixel circuit 10 closest to the secondary display area AA2. The fourth connection wire 5 is disposed on a source-drain layer of the pixel circuit 10. That is to say, in a case where the pixel density of the secondary display area AA2 is relatively high and there are many connection wires, the source 181 of the pixel circuit 10 closest to the secondary display area AA2 can be extended to the secondary display area AA2 to form the fourth connection wire 5, and the first electrode 21 of the light emitting device 20 closest to the primary display area AA1 can be connected with the fourth connection wire 5 through via holes on respective insulation layers. Since the fourth connection wire 5 connects the light emitting device 20 closest to the primary display area AA1 and the pixel circuit 10 closest to the secondary display area AA2, the length of the fourth connection wire 5 extending into the secondary display area AA2 is very short, without affecting a light transmission effect of the secondary display area AA2 and a shaping effect of the camera.

Referring to FIGS. 7, 8 and 10, the light emitting device 20 may include a first electrode 21, a pixel definition layer 22, a light emitting layer set 23 and a second electrode 24. The first electrode 21 may be an anode (pixel electrode).

Referring to FIGS. 7 and 8, the first electrode 21 and the second connection wire 32 may be disposed on the same conductive layer, that is, the second conductive layer 43 may include the first electrode 21 and the second connection wire 32. When the first electrode 21 is connected with the second connection wire 32, the first electrode 21 and the second connection wire 32 can only be used as an integral structure. When the first electrode 21 is connected with the first connection wire 31, the connecting can be realized through the via hole on the first insulation layer 42.

Referring to FIG. 10, the first electrode 21 and the second connection wire 32 may be disposed on the same conductive layer, that is, the third conductive layer 45 may include the first electrode 21 and the second connection wire 32. When the first electrode 21 is connected with the second connection wire 32, the first electrode 21 and the second connection wire 32 can only be used as an integral structure. When the first electrode 21 is connected with the first connection wire 31, the connecting can be realized through the via hole on the second insulation layer 44. When the first electrode 21 is connected with the third connection wire 34, the connecting can be realized through the via hole on the first insulation layer 42 and the via hole on the second insulation layer 44.

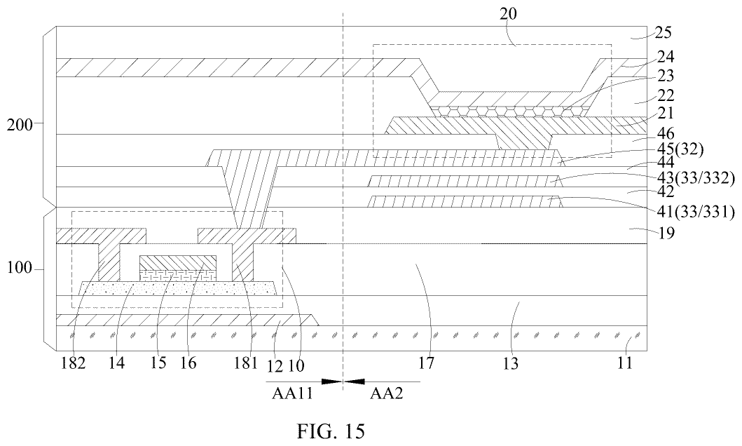

It should be noted that the first electrode 21 and the second connection wire 32 may be disposed on different conductive layers. For example, with reference to FIG. 14, a second insulation layer 44 can be disposed on a side of the second conductive layer 43 away from the substrate, and the first electrode 21 can be disposed on a side of the second insulation layer 44 away from the substrate. The first electrode 21 is connected with the first connection wire 31 and the second connection wire 32 through the via holes on respective insulation layers, and a specific connection manner will not be repeated here. For example, with reference to FIG. 15, a third insulation layer 46 may be disposed on a side of the third conductive layer 45 away from the substrate, and the first electrode 21 may be disposed on a side of the third insulation layer 46 away from the substrate. The first electrode 21 is connected with the first connection wire 31, the second connection wire 32 and the third connection wire 34 through the via holes on respective insulation layers, and a specific connection manner will not be repeated here.

Moreover, referring to FIGS. 14 and 15, since the material of the compensation portion 33 is a transparent material, the compensation portion 33 can also be disposed in the secondary display area AA2.

A side of the first electrode 21 away from the substrate 11 is provided with a pixel definition layer 22, an opening is disposed on the pixel definition layer 22, and a light emitting layer set 23 is disposed in the opening. A side of the light emitting layer set 23 away from the substrate 11 is provided with a second electrode 24, and the second electrode 24 may be a cathode (common electrode), and the second electrode 24 is connected to a ground line VSS.

The light emitting layer set 23 may include a hole injection layer, a hole transport layer, a light emitting layer, an electron transport layer and an electron injection layer stacked in sequence. The hole injection layer is in contact with the first electrode 21, and the electron injection layer is in contact with the second electrode 24. Note that, in other example embodiments of the present disclosure, the light emitting layer set 23 may only include the hole transport layer, the light emitting layer and the electron transport layer, and the light emitting layer set 23 may also have other structures, and its specific structure may be configured as required.

A side of the second electrode 24 away from the substrate 11 is provided with an encapsulation layer set 25. The encapsulation layer set 25 can be disposed as a plurality of layers, and the encapsulation layer set 25 can include an organic layer and an inorganic layer. Specifically, the encapsulation layer set 25 can include a first inorganic layer, an organic layer disposed on a side of the first inorganic layer away from the substrate 11 and a second inorganic layer disposed on a side of the organic layer away from the substrate 11. Materials of the first inorganic layer, the organic layer and the second inorganic layer will not be repeated here. Note that, the encapsulation layer set 25 may also include more layers or fewer layers.

In some other example embodiments of the present disclosure, a touch layer set may be disposed on a side of the package layer set 25 away from the substrate 11, and a touch function may be realized through the touch layer set. A polarizer is disposed on a side of the touch layer set away from the substrate 11, and a cover plate is disposed on a side of the polarizer away from the substrate 11.

Based on the same inventive concept, example embodiments of the present disclosure provide a display device, which may include any one of the above-mentioned display panels and a photosensitive sensor. The specific structure of the display panel has been described in detail above, and thus it will not be repeated here.

The photosensitive sensor is disposed on the non-display side of the display panel, and an orthographic projection of the photosensitive sensor on the display side is at least partially overlapped with the secondary area. For example, an orthographic projection of the photosensitive sensor on the display side may be overlapped with the secondary area, and an orthographic projection of the photosensitive sensor on the display side can be located within the secondary display area, and so on.

A specific type of the display device is not particularly limited, and any type of display device commonly used in the art can be used, such as mobile devices such as mobile phones, wearable devices such as watches, VR devices, etc. . . . Those skilled in the art can make a corresponding selection according to a specific use of the display device, and details are not repeated here.

It should be noted that in addition to the display panel, the display device also includes other necessary parts and components. Taking a display as an example, such as a casing, a circuit board, a power line, etc., those skilled in the art can make corresponding supplements according to specific usage requirements of the display device, which will not be repeated here.

Compared with the prior art, beneficial effects of the display device provided by example embodiments of the present disclosure is the same as beneficial effects of the display panel provided by the above example embodiments, and will not be repeated here.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A display panel with a primary display area and a secondary display area adjacent to each other, wherein the display panel comprises:
a plurality of light emitting devices arranged in an array in the secondary display area, comprising a first light emitting device and a second light emitting device;
a plurality of pixel circuits arranged in an array in the primary display area, comprising a first pixel circuit and a second pixel circuit;
a plurality of first connection wires connected between the first light emitting device and the first pixel circuit;
a plurality of second connection wires connected between the second light emitting device and the second pixel circuit, wherein a capacitance per unit area of the second connection wires is smaller than a capacitance per unit area of the first connection wires; and
a plurality of compensation portions correspondingly connected to the plurality of the second connection wires.

2. The display panel according to claim 1, wherein:
the first light emitting device and the second light emitting device are located in the same row and have the same color, and the first light emitting device is closer to the primary display area than the second light emitting device;
the first pixel circuit is closer to the secondary area than the second pixel circuit;
the second connection wires are disposed on a side of the first connection wires away from the pixel circuits; and
capacitances of the plurality of first connection wires and capacitances of the plurality of second connection wires connected with a plurality of first light emitting devices and a plurality of second light emitting devices in the same row increases or decreases linearly and sequentially along a direction of the secondary display area pointing to the primary display area.

3. The display panel according to claim 2, wherein the first light emitting device and the second light emitting device are red light emitting devices and/or blue light emitting devices.

4. The display panel according to claim 1, wherein the display panel further comprises:
a substrate;
a first conductive layer disposed on a side of the substrate;
a first insulation layer disposed on a side of the first conductive layer away from the substrate; and
a second conductive layer disposed on a side of the first insulation layer away from the substrate.

5. The display panel according to claim 4, wherein the first conductive layer comprises the first connection wires, the second conductive layer comprises the second connection wires, and the compensation portions are disposed at the first conductive layer and/or the second conductive layer.

6. The display panel according to claim 5, wherein one compensation portion of the plurality of compensation portions comprises one or both of a first compensation portion and a second compensation portion; and the first compensation portion is disposed at the first conductive layer, and the second compensation portion is disposed at the second conductive layer.

7. The display panel according to claim 6, wherein the second compensation portion is disposed in a patterned manner, and a partial edge of the second compensation portion is connected with one second connection wire of the plurality of second connection wires.

8. The display panel according to claim 4, wherein the display panel further comprises:
a second insulation layer disposed on a side of the second conductive layer away from the substrate; and
a third conductive layer disposed on a side of the second insulation layer away from the substrate;
wherein the third conductive layer comprises the second connection wires, the second conductive layer comprises the first connection wires, and the compensation portions are disposed at the first conductive layer and/or the second conductive layer and/or the third conductive layer.

9. The display panel according to claim 8, wherein one compensation portion of the plurality of compensation portions comprises at least one of a first compensation portion disposed at the first conductive layer, a second compensation portion disposed at the second conductive layer, or a third compensation portion disposed at the third conductive layer.

10. The display panel according to claim 6, wherein the first compensation portion comprises:
a first portion connected to one second connection wire of the plurality of second connection wires, wherein an orthographic projection of the first portion on the substrate is not overlapped with an orthographic projection of the second connection wire on the substrate; and
a second portion connected to the first portion, wherein an orthographic projection of the second portion on the substrate is located within the orthographic projection of the second connection wire on the substrate.

11. The display panel according to claim 9, wherein the second compensation portion comprises:
a third portion connected to one second connection wire of the plurality of second connection wires, wherein an orthographic projection of the third portion on the substrate is not overlapped with an orthographic projection of the second connection wire on the substrate; and
a fourth portion connected to the third portion, wherein an orthographic projection of the fourth portion on the substrate is located within the orthographic projection of the second connection wire on the substrate.

12. The display panel according to claim 9, wherein the third compensation portion is disposed in a patterned manner, and a partial edge of the third compensation portion is connected with one second connection wire of the plurality of second connection wires.

13. (canceled)

14. The display panel according to claim 9, wherein the compensation portions are disposed at the primary display area, and wherein the primary display area comprises:
a normal display area; and
a transition area disposed between the secondary display area and the normal display area, wherein the pixel circuits are disposed at the transition area, and the compensation portions are disposed at the transition area.

15. The display panel according to claim 14, wherein a plurality of pixel circuits in the same row comprise:
a first set of pixel circuits disposed close to the secondary display area;
a second set of pixel circuits disposed on a side of the first set of pixel circuits away from the secondary display area; and
a third set of pixel circuits disposed on a side of the second set of pixel circuits away from the secondary display area;
wherein the first set of pixel circuits is connected with the light emitting devices through the first conductive layer, the second set of pixel circuits is connected with the light emitting devices through the second conductive layer, and the third set of pixel circuits is connected with the light emitting devices through the third conductive layer.

16. The display panel according to claim 15, wherein the display panel further comprises:
a plurality of third connection wires disposed at the first conductive layer, wherein the plurality of third connection wires are correspondingly connected between the first set of pixel circuits and the plurality of light emitting devices, the plurality of first connection wires are correspondingly connected between the second set of pixel circuits and the plurality of light emitting devices, and the plurality of second connection wires are correspondingly connected between the third set of pixel circuits and the plurality of light emitting devices.

17. The display panel according to claim 16, wherein:
the first compensation portion is spaced apart from the third connection wires, and is located on a side of the third connection wires away from the secondary display area; and
the second compensation portion is spaced apart from the first connection wires, and is located on a side of the first connection wires away from the secondary display area.

18. The display panel according to claim 17, wherein ends of a plurality of first compensation portions close to the secondary display area are aligned, and ends of a plurality of second compensation portions close to the secondary display area are aligned.

19. The display panel according to claim 18, wherein:
the first compensation portion comprises:
a first compensation section connected to one second connection wire of the plurality of second connection wires; and
a first dummy section, spaced apart from the first compensation section and located on a side of the first compensation section close to the secondary display area;
the second compensation portion comprises:
a second compensation section connected to the second connection wire; and
a second dummy section, spaced apart from the second compensation section and located on a side of the second compensation section close to the secondary display area;
wherein areas of orthographic projections of a plurality ones of the first compensation section on the substrate are the same, and areas of orthographic projections of a plurality ones of the second compensation section on the substrate are the same; and
wherein ends of a plurality ones of the first dummy section close to the secondary display area are aligned, and ends of a plurality ones of the second dummy section close to the secondary display area are aligned.

20. The display panel according to claim 15, wherein the plurality of light emitting devices in the same row comprise:
a plurality of green light emitting devices sequentially and correspondingly connected to the plurality of pixel circuits in the same row close to the secondary display area; and
a plurality of red light emitting devices and a plurality of blue light emitting devices alternately and correspondingly connected to the plurality of pixel circuits in the same row away from the secondary display area.

21-23. (canceled)

24. A display device, comprising a display panel with a primary display area and a secondary display area adjacent to each other and a photosensitive sensor,
wherein the display panel comprises: a plurality of light emitting devices arranged in an array in the secondary display area, comprising a first light emitting device and a second light emitting device; a plurality of pixel circuits arranged in an array in the primary display area, comprising a first pixel circuit and a second pixel circuit; a plurality of first connection wires connected between the first light emitting device and the first pixel circuit; a plurality of second connection wires connected between the second light emitting device and the second pixel circuit, wherein a capacitance per unit area of the second connection wires is smaller than a capacitance per unit area of the first connection wires; and a plurality of compensation portions correspondingly connected to the plurality of the second connection wires; and
wherein the photosensitive sensor disposed at a non-display side of the display panel, wherein an orthographic projection of the photosensitive sensor on a display side is at least partially overlapped with the secondary display area.
